(19) United States
(12) Patent Application Publication
(10) Pub. No.: US 2024/0378343 A1
(43) Pub. Date: Nov. 14, 2024

(54) INFORMATION PROCESSING APPARATUS AND COMPUTER PROGRAM PRODUCT

(71) Applicant: TAKUMO Inc., Kawasaki-shi (JP)

(72) Inventor: Hitoshi OKAMURA, Kawasaki-shi (JP)

(21) Appl. No.: 18/766,821

(22) Filed: Jul. 9, 2024

Related U.S. Application Data
(63) Continuation of application No. PCT/JP2022/047197, filed on Dec. 21, 2022.

(30) Foreign Application Priority Data
Jan. 11, 2022 (JP) 2022-002519

(51) Int. Cl. G06F 30/20

(52) U.S. Cl. CPC G06F 30/20

(57) ABSTRACT

According to an embodiment, an information processing apparatus comprises a processing unit including: a template setting unit that sets a template for a predetermined object according to settings on a user terminal to generate a simulation result in response to input of a parameter; a parameter-related value setting unit that sets a value related to the parameter according to the settings on the user terminal; a simulation unit that enters the parameter set by the parameter-related value setting unit into the template set by the template setting unit to generate a simulation result; and a result data creation unit that presents information based on the simulation result generated by the simulation unit to the user terminal.

### CROSS-REFERENCE TO RELATED APPLICATION

This application is a bypass continuation application of international application No. PCT/JP2022/047197 having an international filing date of Dec. 21, 2022 and designating the United States of America; the entire content of which is incorporated herein by reference.

### FIELD

Embodiments described herein relate generally to an information processing apparatus and a computer program product. Specifically, embodiments described herein relate to technology for facilitating the generation of simulation data, such as a simulation model of an electronic component or a semiconductor device and a schematic or netlist of an electronic circuit. The embodiments may be applicable not only to the fields of electronic components and electronic equipment but also to various fields such as machinery and natural phenomena.

### BACKGROUND

In an electronic system, semiconductor integrated circuits, discrete semiconductors such as transistors and diodes, passive devices such as resistors, capacitors, and inductors, connectors, and the like are arranged and wired on printed circuit boards, and the printed circuit boards are connected together with wiring or to a power source and other electronic components to achieve the desired functions.

In the case of a semiconductor manufacturing process, various design information required for the design, called a process design kit (PDK), is prepared to design a semiconductor integrated circuit or a discrete semiconductor device that uses the manufacturing process. In the PDK, SPICE parameters are those necessary for circuit design.

SPICE, Simulation Program with Integrated Circuit Emphasis, is a simulator developed at the University of California, Berkeley. Specifically, SPICE is a simulator that models active devices such as transistors and diodes, and passive devices such as resistors, capacitors, and inductors using SPICE models, which are characteristic expressions that combine theoretical, empirical, and approximate expressions, and SPICE parameters, which are their coefficients, and allows the operation of a circuit that combines the active and passive devices to be represented by a combination of the models and simulated on a computer.

Various types of SPICE models, such as BSIM3 and BSIM4, have been developed and are widely used. Once a specific SPICE model has been determined for a developed device based on the device type, required accuracy, and the like, there is a need to determine SPICE parameters that faithfully represent the operation of the device.

It is necessary to view a variety of characteristics measured from different perspectives to properly represent the operation of a transistor. In addition, there are more than 100 SPICE parameters for a MOS transistor, and it is not easy to find the optimal combination of SPICE parameters that faithfully represent all of the characteristics. The SPICE parameters are optimized step by step by a specialized engineer, who is well-versed in the operating principles of the device and SPICE, using specialized software; therefore, the process is extremely sophisticated and time-consuming.

Next, a description will be given of the implementation of a semiconductor integrated circuit. A semiconductor integrated circuit is typically designed using SPICE parameters from the PDK and various software tools. As illustrated in FIG. 6, to implement a semiconductor integrated circuit, first, the specifications are designed, the circuit is designed, and its operation is verified. Next, a layout is designed for use in fabricating the circuit on a semiconductor wafer. This is followed by design verification, including operational and physical verification. The process then moves to a manufacturing step for prototyping.

To design a circuit, a designer first designs the circuit as a topology. For example, a circuit with a topology as illustrated in FIG. 7 is designed to implement a voltage comparator. The circuit is formed by connecting NMOS transistors 601 to 605, PMOS transistors 606 and 607, resistors 608 and 609, and a current source. Although the current source is also a circuit of transistors and passive devices, the details of the circuit are not described here.

The designer then adjusts the circuit constants of the NMOS transistors 601 to 605, the PMOS transistors 606 and 607, and the resistors 608 and 609 such that the circuit has the desired characteristics, thereby completing the circuit. The typical circuit constants of a MOS transistor are the gate width (W) and the gate length (L).

FIG. 8 illustrates a schematic plan view of a MOS transistor, in which three important electrodes of the MOS transistor, a source 701, a drain 702, and a gate 703, are connected through a contact 706 to other devices in the circuit and a power source by conductors. Although not illustrated, in general, the board-side region of a bulk transistor is also connected to a constant bias potential such as a power source.

When flowing in a direction from the source 701 to the drain 702 in a state where a constant voltage is applied between the gate 703 and the source 701, a current 707 is approximately proportional to a gate width (W) 704, which is the width of a current path directly below the gate, and inversely proportional to the gate length (L) 705, which is the length of the current path. Therefore, the operating characteristics of the transistor in the circuit can be changed by changing the gate width and length.

The constants of a circuit are typically optimized by simulating the operation of the circuit using a SPICE simulator. However, as the number of devices in a circuit increases, the number of combinations of circuit constants for each device increases exponentially, requiring the designer to predict the effects of the circuit constants and then systematize the optimization procedure. It is difficult for an inexperienced engineer to optimize all the circuit constants in a complex circuit, and it is also an extremely inefficient task that requires even a skilled engineer to perform without leaving a computer for long periods of time.

SPICE simulation, i.e., a circuit simulator, is not essential for the development of discrete semiconductors per se, as they often have only one or very few devices mounted on them. Rather, device simulation with device structures and materials as parameters is used to predict device characteristics from the physical phenomena of the device through simulation. Passive devices are also designed through device simulation, prototyping, and desktop calculation, without the need for simulation in the design of the devices themselves.

However, when electronic components designed and developed in this manner are arranged on a printed circuit board, and simulation is used for board-level or module-level circuit design intended to realize greater functionality, simulation models of the electronic components are required. Accordingly, it is necessary to prepare SPICE models for the electronic components, including discrete semiconductors.

FIG. 9 illustrates a simple equivalent circuit of a single transistor enclosed in a package. Because of the large current flow, semiconductors that make up a device are larger than those of a semiconductor integrated circuit, and the package dimensions are also somewhat larger. Therefore, parasitic inductances 803 to 805 generated by electrode metal plates inside the package, electrodes for soldering to the printed circuit board, and the like, a resistor 806 for preventing electrostatic breakdown, and a diode 802 are reproduced around a MOS transistor 801.

A transistor is sometimes called an active device, while a resistor, a capacitor, a coil (inductor), and the like are called passive devices. Since these passive devices also have a finite physical size and are provided as electronic components enclosed in a package, parasitic components other than the originally intended electrical characteristics affect the high-frequency characteristics. For example, a large-capacitance capacitor component does not function as expected in response to high-frequency voltage changes because resistance and inductance components are inserted as parasitic components in series with the capacitor.

Simulation at the printed circuit board level often requires a simulation model that includes such a package in order to represent a transient response. There is not enough supply of such SPICE models for the vast number of electronic components available in the electronic component market. Therefore, when board-level or module-level designers undertake model-based design, they have to have a specialist develop a SPICE model or the like, which requires long preparation times and high preparation costs.

As a result, designers often abandon pre-prototype simulation and instead perform operation verification and optimization through repeated prototyping and adjustments; thus, simulation-based design, such as that used for semiconductor integrated circuits, has not become widespread.

With regard to semiconductor circuit design, to alleviate the above-mentioned complexity problem, a technique has been proposed that aims to simplify the design by dividing a circuit into blocks and defining optimization methods and guidelines for each block as a template.

However, the technique only provides circuit designers with suggestions for optimizing circuit constants and does not provide any means for automating the process. Hence, the design methodology is strictly fixed, and the entire system needs to be installed on a computer, which creates a high barrier to replacing the design method that the user has used in the past, and there are also cost issues. In addition, since the design for each block and the method of presenting the optimization suggestions are analytical and attempt to optimize bias conditions, the procedures for optimizing circuit constants are complicated and it is difficult to achieve sufficient accuracy. Moreover, it is not possible to optimize transient characteristics if the circuit includes a capacitor or an inductor, or by taking into account the parasitic capacitance of a transistor. Furthermore, the template is for a small unit circuit; therefore, the technique cannot be applied to the SPICE parameters of a single semiconductor device or a simple equivalent circuit model of an electronic device.

Reference may be made to the following art:
Patent Document 1: Japanese Patent Publication No. JP 2017-068646 A
Patent Document 2: Japanese Patent Publication No. JP 2019-040590 A

As described above, the design of electronic devices has the following problems: users cannot easily and inexpensively obtain a target object, such as a simulation model and schematic of an electronic circuit that can be simulated; providers of services, such as simulation model development and circuit design, find it difficult to recoup high software license fees and labor costs; and it is difficult for both parties to recruit engineers with the specialized knowledge they need.

According to the inventor's observations, there are similar problems not only in the fields of semiconductors, electronic components, and electronic equipment, but also in various fields such as machinery and natural phenomena.

### SUMMARY

It is therefore an object of the present disclosure to provide an information processing apparatus and a computer program product that enable a user to obtain a target object easily and at a low cost.

According to an embodiment, an information processing apparatus comprises a processing unit including: a template setting unit that sets a template for a predetermined object according to settings on a user terminal to generate a simulation result in response to input of a parameter; a parameter-related value setting unit that sets a value related to the parameter according to the settings on the user terminal; a simulation unit that enters the parameter set by the parameter-related value setting unit into the template set by the template setting unit to run a simulation to generate a simulation result; and a result data creation unit that presents information based on the simulation result generated by the simulation unit to the user terminal.

### BRIEF DESCRIPTION OF THE DRAWINGS

FIG. 1 is a block diagram illustrating a simulation data generation system according to a first embodiment;

FIG. 2 is a block diagram illustrating a simulation data generation system according to a second embodiment;

FIG. 3 is a block diagram illustrating a simulation data generation system according to a third embodiment;

FIG. 4 is a diagram for explaining a simulation data generation system according to a fourth embodiment;

FIG. 5 is a diagram illustrating a detailed configuration of a processing unit of the simulation data generation system;

FIG. 6 is a flowchart illustrating the flow of designing a semiconductor integrated circuit;

FIG. 7 is a diagram illustrating an example of a circuit topology;

FIG. 8 is a schematic plan view of a MOS transistor;

FIG. 9 is a circuit diagram illustrating an equivalent circuit of a single transistor;

FIG. 10 is a diagram illustrating graphs of the current-voltage characteristics of a MOS transistor in a semiconductor integrated circuit;

FIG. 11 is a diagram illustrating the input/output voltage waveforms of the semiconductor integrated circuit in FIG. 7;

FIG. 12 is a diagram illustrating the output voltage transient characteristics of the single transistor in FIG. 9;

FIG. 13 is a diagram illustrating a preliminary simulation unit provided inside an information input unit; and

FIG. 14 is a diagram illustrating an example of a procedure for searching for a compatible or alternative product.

### DETAILED DESCRIPTION

In the following, exemplary embodiments will be described with reference to the accompanying drawings.

### First Embodiment

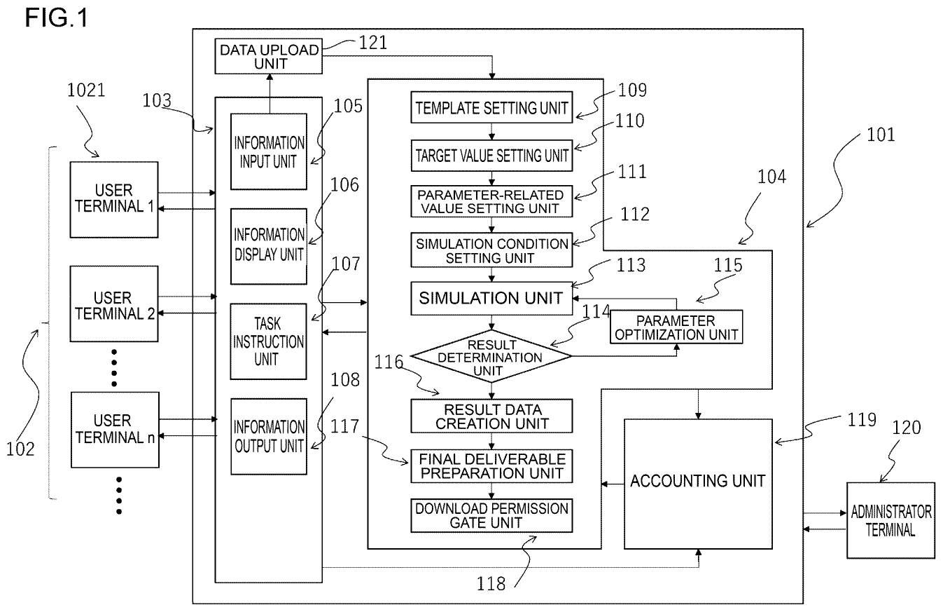

FIG. 1 is a block diagram of a system according to a first embodiment. A simulation data generation system 101 of this embodiment includes a user interface 103, a processing unit 104, and an accounting unit 119. The simulation data generation system 101 is managed as a whole through an administrator terminal 120 used by an administrator.

The simulation data generation system 101 may be configured as a stand-alone simulation data generator, i.e., a server. Alternatively, the simulation data generation system 101 may include a plurality of hardware resources that communicate with each other and cooperate to perform processing. In the control circuit of the simulation data generation system 101, the CPU loads a computer program from the ROM into the RAM and executes it, thereby operating as the processing unit 104. The processing unit 104 includes a template setting unit 109, a target value setting unit 110, a parameter-related value setting unit 111, a simulation condition setting unit 112, a simulation unit 113, a result determination unit 114, a parameter optimization unit 115, a result data creation unit 116, a final deliverable preparation unit 117, and a download permission gate unit 118.

A user terminal group 102 accesses the processing unit 104 via the user interface 103. The simulation data generation system 101 separately performs a plurality of jobs requested to be processed by the user terminal group 102. The user interface 103 may be a WEB system for communicating with the user terminal group 102. The user interface 103 includes an information input unit 105, an information display unit 106, a task instruction unit 107, and an information output unit 108.

The simulation data generation system 101 generates simulation data as a deliverable. The simulation data to be generated as a deliverable is electronic data that can be simulated by a simulator, such as SPICE parameters of a semiconductor integrated circuit, an equivalent circuit model, an input/output buffer information specification (IBIS) model, schematic data representing a schematic of an electronic circuit, a netlist, and the like.

A user terminal 1021 in the user terminal group 102 enters a template, a target value, parameter-related values of (initial values parameters, allowable ranges of parameters, program parameters, etc.), and simulation conditions into the information input unit 105 of the user interface 103. The template represents a simulation model and topology of a deliverable that corresponds to an object for which simulation data is to be generated. The target value is a target value for the simulation data of the object.

In response to the settings by a provider that operates the simulation data generation system 101 from the administrator terminal 120, the processing unit 104 may directly or indirectly recommend or specify a template, a target value, parameter-related values, and simulation conditions to the user terminal 1021. The user terminal 1021 may enter the recommended or specified template, target value, parameter-related values, and simulation conditions into the information input unit 105 of the user interface 103. The user terminal 1021 may also enter a template created by the user into the information input unit 105 of the user interface 103. Similarly, the user terminal 1021 may enter a target value, parameter-related values, and simulation conditions created by the user into the information input unit 105 of the user interface 103.

In response, the template setting unit 109 sets a template according to an object for which simulation data is to be generated. The target value setting unit 110 sets a target value for the simulation data of the object. The parameter-related value setting unit 111 sets a parameter-related value that changes the characteristics of the template. The simulation condition setting unit 112 sets simulation conditions, a desired allowable error, and the maximum number of optimization trials.

The user terminal 1021 instructs the processing unit 104 to generate a target deliverable through the task instruction unit 107. In response, the simulation unit 113 of the processing unit 104 retrieves the template, target value, parameter, simulation conditions, desired allowable error, and maximum number of optimization trials set in the template setting unit 109, target value setting unit 110, parameter-related value setting unit 111, and simulation condition setting unit 112. The simulation unit 113 then runs a simulation based on the retrieved template, target value, parameter, and simulation conditions, and generates a simulation result. The simulation unit 113 sends the generated simulation result to the result determination unit 114. Note that the simulation unit 113 may be the same (type of) simulator as the one used by the user, specifically, a SPICE simulator.

The result determination unit 114 compares the simulation result generated by the simulation unit 113 with the target value set in the target value setting unit 110 to find an error. The result determination unit 114 determines whether the error is equal to or less than the desired allowable error.

When the result determination unit 114 determines that the error is greater than the desired allowable error, the parameter optimization unit 115 optimizes the parameter set in the parameter-related value setting unit 111 with reference to the target value set by the target value setting unit 110. In this manner, the parameter optimization unit 115 adjusts and changes the parameter. The parameter optimization unit 115 causes the simulation unit 113 to rerun the simulation using the adjusted and changed parameter. The parameter optimization unit 115 increments (by 1) the number of optimization trials each time it performs optimization; it can perform optimization until the number of optimization trials reaches the maximum number of optimization trials set in the simulation condition setting unit 112.

The result determination unit 114 compares the new simulation result generated by the simulation unit 113 with the target value to determines whether the error is equal to or less than the desired allowable error. The simulation unit 113, the result determination unit 114, and the parameter optimization unit 115 continue the loop process until the result determination unit 114 determines that the error is equal to or less than the desired allowable error, i.e., the simulation result is satisfactory. The result determination unit 114 may make the determination based not only on the absolute value of the error but also on the degree of error reduction; it may determine that the error is equal to or less than the desired allowable error when the degree of reduction reaches a predetermined threshold, i.e., when it is saturated. In addition, the simulation condition setting unit 112 may be configured to prioritize the maximum number of optimization trials over the determination of the result determination unit 114.

On the other hand, when the result determination unit 114 determines that the error is equal to or less than the desired allowable error, i.e., the simulation result is satisfactory, the result data creation unit 116 creates a processing result evaluation report as a final report. The processing result evaluation report includes data comparing the simulation result generated through the simulation performed by the simulation unit 113 using the optimized parameter and template with the target value set by the target value setting unit 110. The result data creation unit 116 presents or displays the processing result evaluation report on the user terminal 1021 through the information display unit 106.

If the error is greater than the desired allowable error, i.e., if the simulation result is not determined to be satisfactory, the result data creation unit 116 may also create a progress report that contains the simulation result and display the progress report on the user terminal 1021 through the information display unit 106. For example, data displayed in the progress report may include an evaluation function value, an index indicating the degree of convergence, the value of each optimization parameter, and the like. The result data creation unit 116 may display or output the progress report including these data in the form of a graph or numerical values; it may further display a waveform resulting from running a simulation such as SPICE or the like. The result data creation unit 116 may display or output the progress report at appropriate times during processing instead of the processing result evaluation report as a final report. As for the display of a waveform resulting from running a simulation such as SPICE, it is the result of running a simulator such as SPICE in the simulation unit 113 using a parameter in the process of optimization, and the waveform itself is output from the simulator.

The final deliverable preparation unit 117 creates a final report containing a deliverable, which mainly includes the template and the optimized parameter. The deliverable is electronic data that can be simulated by a simulator, such as SPICE parameters of a semiconductor integrated circuit, an equivalent circuit model, an IBIS model, schematic data representing a schematic of an electronic circuit, a netlist, or the like. In contrast, the processing result evaluation report created by the result data creation unit 116 is electronic data that cannot be simulated by a simulator.

The download permission gate unit 118 is initially closed (i.e., in a state where it controls the provision of the final report to be rejected). For this reason, the user terminal 1021 cannot download thereto the final report containing the simulation data, i.e., the deliverable, generated by the final deliverable preparation unit 117.

The accounting unit 119 calculates the system usage fee based on the computer resources and the like used by the simulation data generation system 101 to obtain the result and the value of the template used. The accounting unit 119 then notifies the user terminal 1021 of the calculated system usage fee through the information display unit 106. The fee and a report of the processing result may be output as an electronic file through the information output unit 108 as necessary.

Meanwhile, the user refers to the processing result evaluation report displayed on the user terminal 1021 through the information display unit 106. When satisfied with the result on the processing result evaluation report, the user uses the user terminal 1021 to: indicate, through the information input unit 105 and/or the task instruction unit 107, that the user is satisfied with the result and agrees to the charges. In response, the accounting unit 119 checks online payment information or the like and determines to release the gate of the download permission gate unit 118.

The download permission gate unit 118 controls whether or not the final report containing the simulation data, i.e., the deliverable, is to be provided to the user terminal 1021. In response to the determination to release the gate from the accounting unit 119, the download permission gate unit 118 permits the download of the deliverable, i.e., controls the provision of the final report containing the deliverable to be permitted. The user terminal 1021 then downloads the deliverable through the information output unit 108, allowing the simulation data obtained as the deliverable to be used locally in the environment of the user terminal 1021.

The accounting unit 119 may be configured to determine to cause the processing unit 104 to generate simulation data again if the user is not satisfied with the result presented in the processing result report before the user terminal 1021 downloads the deliverable. In this case, based on an agreement between the provider and the user, simulation data is generated again by changing part or all of the contents of one or more of the following: template selection, target value setting, parameter-related value setting, and simulation condition setting.

In addition, if there is compensation between the user and the provider in lieu of direct charging, the accounting unit 119 may use it to determine an appropriate process. The download permission gate unit 118 may use the usage fee required to generate the deliverable calculated by the accounting unit 119 to control whether or not to provide the final report containing the deliverable.

### Example

The following is an example of generating a basic SPICE model of a semiconductor MOS transistor to illustrate the specific details of the process. While there are various types of SPICE models, it is assumed here that the template setting unit 109 selects and sets the BSIM4 model as the template.

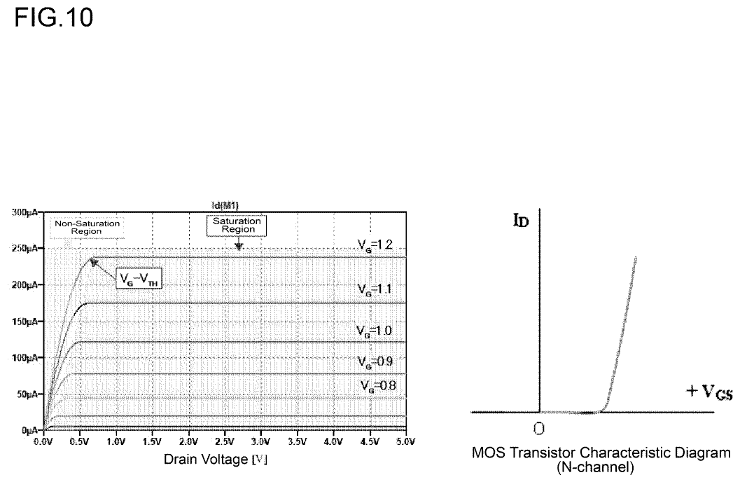

For example, the I-V curve of the MOS transistor may be set as a target value, as illustrated in FIG. 10.

The user terminal 1021 sets the default parameters of BSIM4 as parameter-related values in the parameter-related value setting unit 111 and also sets the voltage to be applied to the MOS transistor, the analysis mode of the SPICE simulator, and the like in the simulation condition setting unit 112. The user terminal 1021 then causes the processing unit 104, through the task instruction unit 107, to search for a combination of SPICE parameters that satisfies all target values.

In this case, algorithms called a genetic algorithm and an evolutionary algorithm are suitable for the error minimization algorithm used by the parameter optimization unit 115; however, other algorithms may be used. Optional parameters for these algorithms may be set through the parameter-related value setting unit 111. The genetic and evolutionary algorithms search for a combination of optimal parameters in a search space so as to minimize an evaluation function, which is a mathematical expression of the difference between a simulation result and a target value. The search range may be the allowable range of the parameters, i.e., the range within which the algorithm of the parameter optimization unit 115 searches for the optimal parameters. In other words, the parameter-related value setting unit 111 may set not only the initial values of parameters but also the allowable range of the parameters (the range within which the parameter optimization unit 115 searches for optimal parameters) and the operation setting parameters of the program. The values related to various parameters, such as the initial values of the parameters, allowable range, program parameters, and the like, are collectively referred to as “parameter-related values”. In addition, there may be a database 201 that stores a plurality of parameter-related values and allowable ranges, and the parameter-related value setting unit 111 may select parameter-related values and an allowable range from the database 201. The parameter-related value setting unit 111 may also set parameters for the simulation unit 113. When the target value is not a specific numerical value but a qualitative one such as a minimum or maximum value, the target characteristic itself or the inverse of the target characteristic may be used as an evaluation function to search for a combination of optimal parameters. That is, the parameter-related value setting unit 111 may set options and parameters for the search algorithm, i.e., general parameters that control the operation of related software as the operation setting parameters of the program.

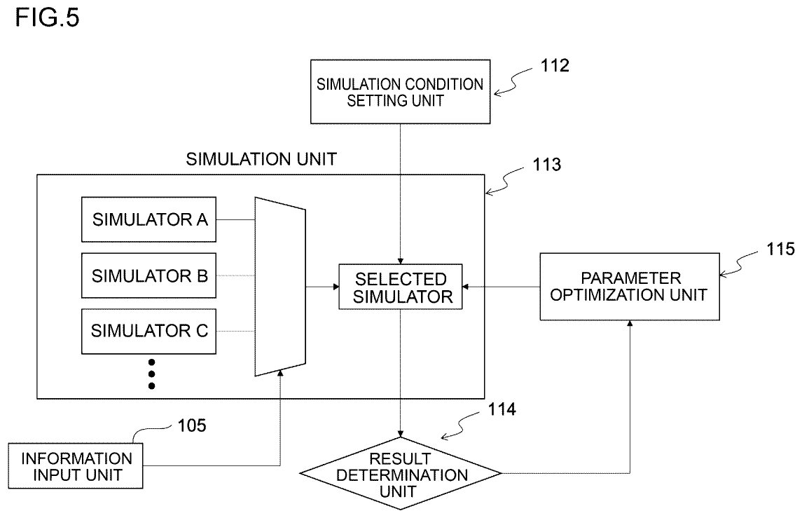

The user terminal 1021 can use parameters for the completed BSIM4 model as they are when locally running a circuit simulation with SPICE. FIG. 5 illustrates an example of the internal structure of the simulation unit 113. When a simulator A, which is the same simulator as a SPICE simulator used for the circuit simulation, and simulators B and C, which are simulators compatible with the SPICE simulator, are specified to the processing unit 104, and the simulation unit 113 selects and sets one of the simulators, it is possible to realize a circuit simulation with the same accuracy as that of the SPICE model generated by the simulation data generation system 101.

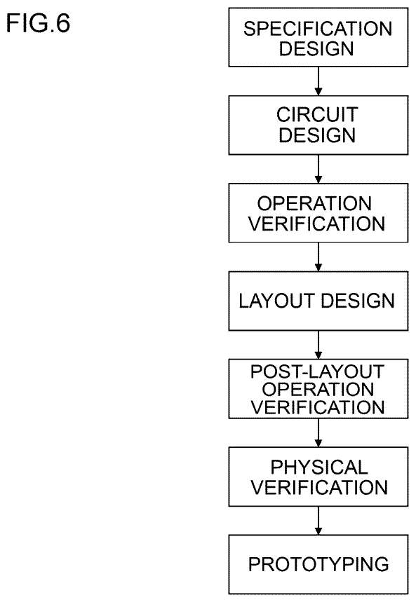

To perform a circuit design for a semiconductor integrated circuit in the flowchart of FIG. 6, first, the template setting unit 109 sets, as a template, a circuit diagram in which some or all of the circuit constants are not set. The template may be created through the information input unit 105, or it may be stored in advance in the user terminal 1021 and uploaded by a data upload unit 121 through the information input unit 105.

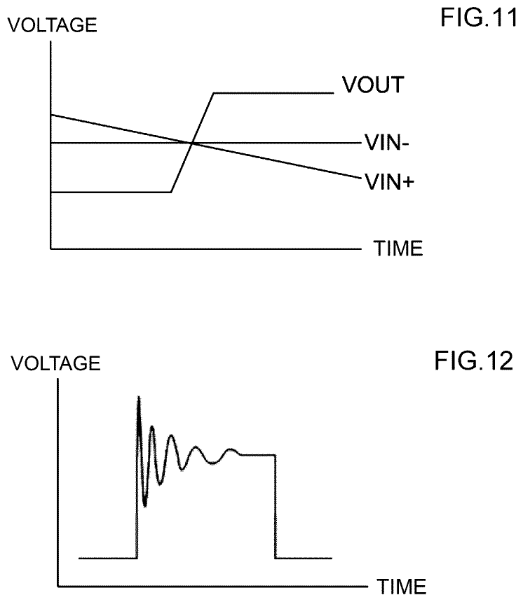

Next, the target value setting unit 110 sets a target value. The target value has the same content as that when a designer designs a circuit using a SPICE simulator, and may be, for example, circuit operation waveforms as illustrated in FIG. 11, which indicate transient and static characteristics at nodes and input/output terminals in the circuit whose characteristics are to be observed.

The parameter-related value setting unit 111 sets parameter-related values to values for the template to operate roughly.

The simulation condition setting unit 112 sets simulation conditions in the same manner as when generating SPICE parameters for a semiconductor device.

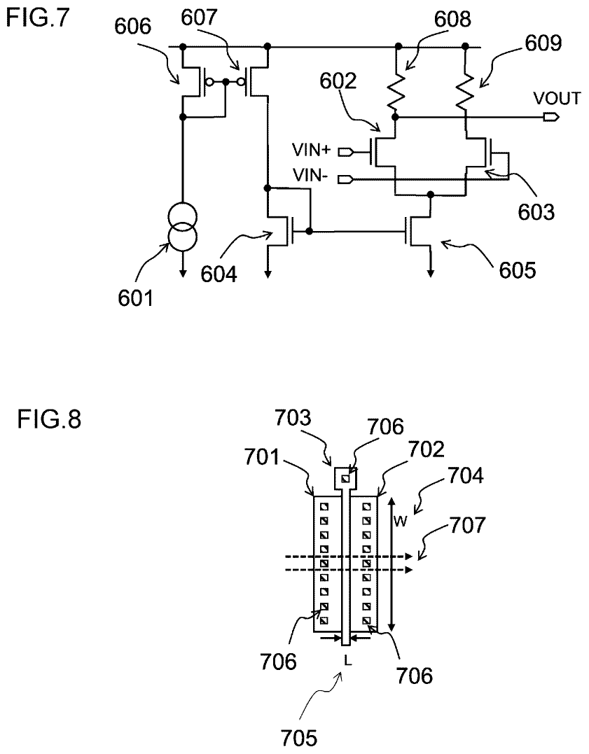

The parameter-related value setting unit 111 or the simulation condition setting unit 112 may also set the relationships between the transistors 602 and 603, 604 and 605, and 606 and 607, which operate as pairs as illustrated in FIG. 7. For example, conditions are set such that transistors of the same size are used. Alternatively, circuit constants may be set in the template set by the template setting unit 109 such that the simulation unit 113 may prioritize them.

The simulation unit 113 performs trial simulations while changing by the parameter optimization unit 115 circuit constants in the SPICE simulator and searches for a combination of circuit constants that, as a result of a determination by the result determination unit 114, brings the circuit operation in the simulation closest to the target value.

In this case, algorithms called a genetic algorithm and an evolutionary algorithm are suitable for the error minimization algorithm used by the parameter optimization unit 115; however, other algorithms may be used.

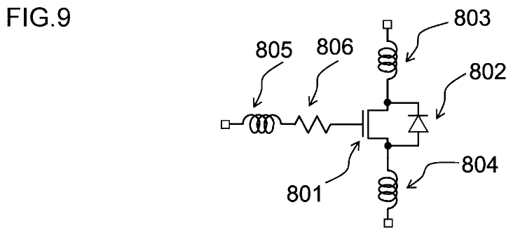

To generate an equivalent circuit simulation model of the single device as illustrated in FIG. 9, first, the target value setting unit 110 sets DC static characteristics as illustrated in FIG. 10 as a target value. The parameter optimization unit 115 generates SPICE parameters of the core MOS transistor 801 and the diode 802 using the DC static characteristics as the target value in the same manner as when generating simulation model for a semiconductor device. The simulation condition setting unit 112 may set a generation flow such that the circuit constants of the passive devices 803, 804, and 805 around the MOS transistor 801 in the equivalent circuit model are optimized as in the circuit design for a semiconductor integrated circuit, using transient response characteristics as illustrated in FIG. 12 as a target value. In addition, the user interface 103 including the task instruction unit 107 may cause the processing unit 104 to perform a task in multiple steps. For example, a task may be broken down into steps when the processing unit 104 is operated through the task instruction unit 107. An example of creating steps when the processing unit 104 is operated through the task instruction unit 107 may be, in the case of a circuit which is a connection of a plurality of subcircuits with different functions, steps for processing the subcircuits in sequence or in parallel and re-optimizing the whole at the end. By changing the evaluation function for each of the subcircuits to a suitable one, it is possible to improve the accuracy of the result and reduce the processing time.

When multiple targets for different characteristics, which require the processing unit 104 to run separate simulations, are set in the target value setting unit 110, the simulation condition setting unit 112 may also make settings such that the processing unit 104 runs multiple simulations in a single optimization trial and simulation results to the simultaneously inputs multiple result determination unit 114.

The user may have different needs and may intend to, for example, based on an existing simulation model, create a simulation model with slightly changed characteristics, change the configuration or version of the simulation model to increase the accuracy or simulation speed, or create a new simulation model that runs on a different simulator and produces the same result as the existing simulation model. In this case, the user may simulate the existing simulation model and enter the result into the information input unit 105 as a target value for optimization.

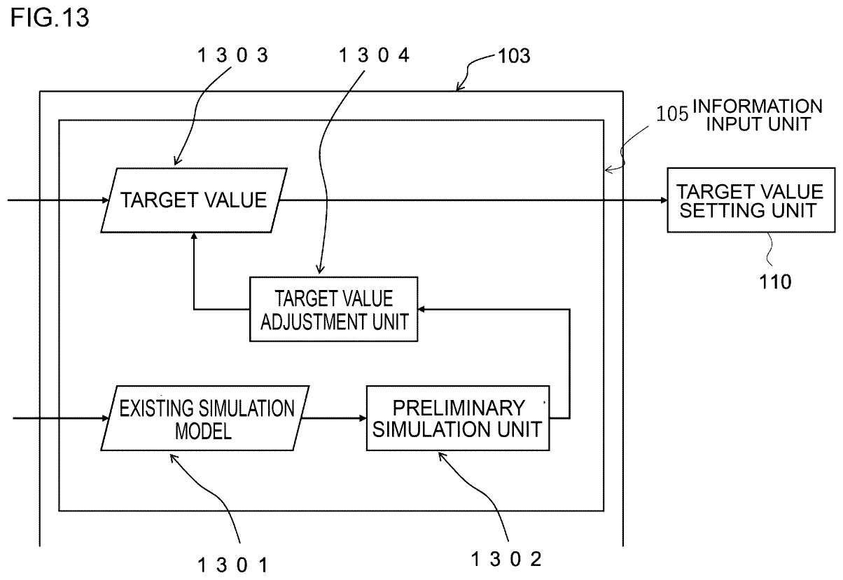

As illustrated in FIG. 13, the information input unit 105 may be provided with a preliminary simulation unit 1302. In this case, the preliminary simulation unit 1302 may simulate an existing simulation model 1301 entered by the user from the user terminal 1021, and the information input unit 105 may provide the result as a target value 1303 to the target value setting unit 110 of the simulation data generation system 101. The simulation model used as the preliminary simulation unit 1302 may be the same as or correspond to the simulator used as the simulation unit 113. In other words, the preliminary simulation unit 1302 and the simulation unit 113 may share the simulator. This allows the target value 1303 to be set more appropriately. Alternatively, the simulator used in the preliminary simulation unit 1302 may be the one that can use the existing simulation model 1301, and the simulation unit 113 may select another simulator that can use a desired simulation model. This allows the simulation result of the existing simulation model 1301 to be set as the target value 1303 for another desired simulation model. Thereby, it is possible to provide functions for converting a simulation model for one simulator into one for another simulator as well as for changing the version or format of a SPICE model. For example, in the case of upgrading a SPICE model version from BSIM3 to BSIM4 or downgrading from BSIM4 to BSIM3, a BSIM model template of the target may be selected as the template. It is also possible to convert from a BSIM model to a functional description of SPICE or VHDL-AMS (a hardware description language for analog and mixed-signal), and similarly, a template of the target may be specified in the desired style.

The information input unit 105 may also be provided with a target value adjustment unit 1304. In this case, the target value adjustment unit 1304 may adjust the target value 1303 resulting from a simulation of the existing simulation model 1301 performed by the preliminary simulation unit 1302 and provide the adjusted target value 1303 to the target value setting unit 110 of the simulation data generation system 101. The target value adjustment unit 1304 sets a new target value that is, for example, 10% higher than the target value 1303 before adjustment. The target value setting unit 110 of the simulation data generation system 101 may set the target value 1303 received from the information input unit 105. This allows the preliminary simulation unit 1302 to appropriately set the target value 1303 without requiring the user to set the target value manually, which is particularly useful for inexperienced users. In addition, when the target value adjustment unit 1304 adjusts the target value 1303, the target value set in the target value setting unit 110 can be made more appropriate. A semiconductor integrated circuit may be transferred to a different process by using SPICE parameters of a PDK different from the original one.

According to the embodiment, the user accesses the simulation data generation system 101, such as a cloud computer, through the user terminal 1021. The template setting unit 109 uses a template specified through the user terminal 1021 or a template selected from a shared database in the cloud as a template for the desired deliverable to be created by the final deliverable preparation unit 117. The parameter optimization unit 115 optimizes the parameters of the template set by the parameter-related value setting unit 111 using a software algorithm that performs common steps. As a result, costs can be reduced for both the user and the provider.

In addition, the user can fully check whether the result of simulation data, which is a deliverable created by the final deliverable preparation unit 117, has reached the target when the download permission gate unit 118 is in a closed state (in a state where it controls the provision of the final report to be rejected), i.e., before paying the fee and receiving the deliverable, with reference to the processing result evaluation report created by the result data creation unit 116.

Furthermore, the accounting unit 119 checks online payment information or the like, and in response to the determination to release the gate from the accounting unit 119, the download permission gate unit 118 permits the download of the deliverable, i.e., controls the provision of the final report containing the deliverable to be permitted. Therefore, there is a benefit to the provider in that they can be reliably paid for the provision of the deliverable.

### Second Embodiment

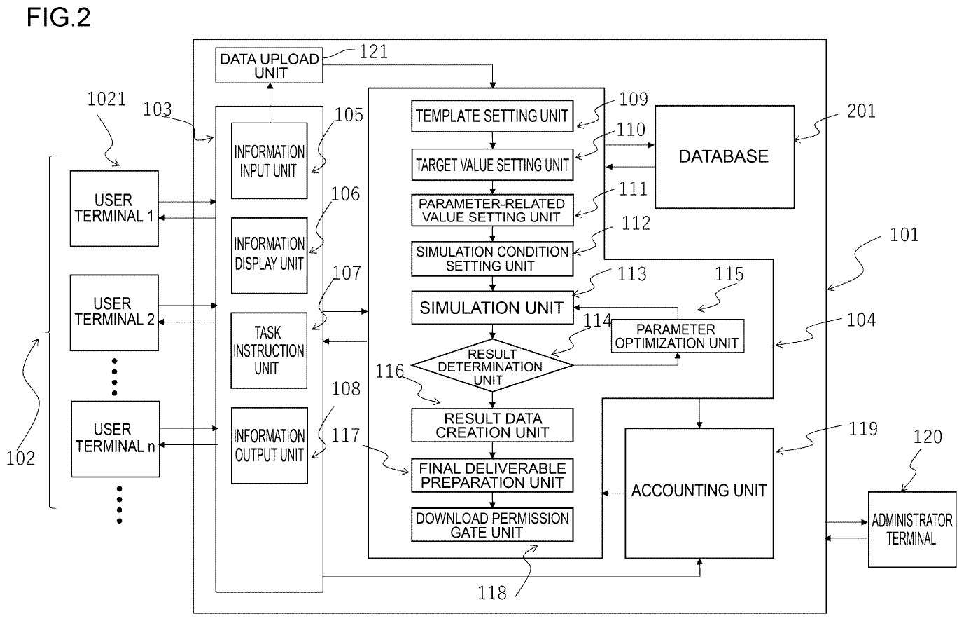

FIG. 2 is a block diagram of a system according to a second embodiment, in which the simulation data generation system 101 of the first embodiment illustrated in FIG. 1 further includes the database 201 that stores a plurality of templates, parameter-related values, and simulation conditions.

The database 201 stores a plurality of templates, parameter-related values, and simulation conditions. Part of the contents of the database 201 may be specified in advance in a template.

The user terminal 1021 in the user terminal group 102 enters a target value into the information input unit 105 of the user interface 103. In response, the target value setting unit 110 sets the target value for the simulation data of the object.

The template setting unit 109 selects a desired template from the database 201 based on the target value set in the target value setting unit 110 and sets the template. The parameter-related value setting unit 111 selects a parameter-related value from the database 201 based on the target value set in the target value setting unit 110 and sets the parameter-related value. The simulation condition setting unit 112 selects a simulation condition, used for the simulation unit 113 to run a simulation, from the database 201 based on the target value set in the target value setting unit 110 and sets the simulation condition.

Alternatively, the template setting unit 109 may set a desired template that the user has selected from the database 201 through the user interface 103 using the user terminal 1021. Similarly, the parameter-related value setting unit 111 may set a parameter-related value that the user has selected from the database 201 through the user interface 103 using the user terminal 1021. The simulation condition setting unit 112 may set a simulation condition that the user has selected from the database 201 through the user interface 103 using the user terminal 1021.

Accordingly, the template setting unit 109, the parameter-related value setting unit 111, and the simulation condition setting unit 112 can refer to the database 201 when selecting a template, a parameter-related value, and a simulation condition, improving processing thereby efficiency. In addition, the user can refer to the database 201 when selecting a template, a parameter-related value, or a simulation condition through the user interface 103 using the user terminal 1021, thereby improving user convenience.

The processing unit 104 may store a history of simulation runs in the database 201. The history of simulation runs includes at least some of the following: a template set in the template setting unit 109, a target value set in the target value setting unit 110, parameter-related values set in the parameter-related value setting unit 111, parameters adjusted and changed by the parameter optimization unit 115, simulation conditions set in the simulation condition setting unit 112, error results determined by the result determination unit 114, a processing result evaluation report created by the result data creation unit 116, whether the user is satisfied with the processing result evaluation report, and a final report generated by the final deliverable preparation unit 117. Thus, the results of simulations performed by the user terminal group 102 can be stored in the database 201 and shared among the user terminal group 102 in the future, thereby improving the simulation data generation system 101 and making it more convenient.

In addition, when the database 201 stores the results of the determination by the result determination unit 114 (i.e., whether the simulation results are satisfactory or not) and whether the user is satisfied with the processing result evaluation report, it is possible to appropriately select a template, a target value, parameters, and simulation conditions from the database 201, thereby further improving the convenience of the simulation data generation system 101.

Furthermore, by storing a history of simulation runs that are of relatively low value to be stored, such as those in which the error is greater than the desired allowable error (i.e., the simulation result is not satisfactory) and those in which the final deliverable is not downloaded even though the error is equal to or less than the desired allowable error (i.e., the simulation is result satisfactory), a larger amount of data can be stored in the database 201 along with the results. This makes it possible to more appropriately select a template, a target value, parameters, and simulation conditions from the database 201, thereby further improving the convenience of the simulation data generation system 101.

### Third Embodiment

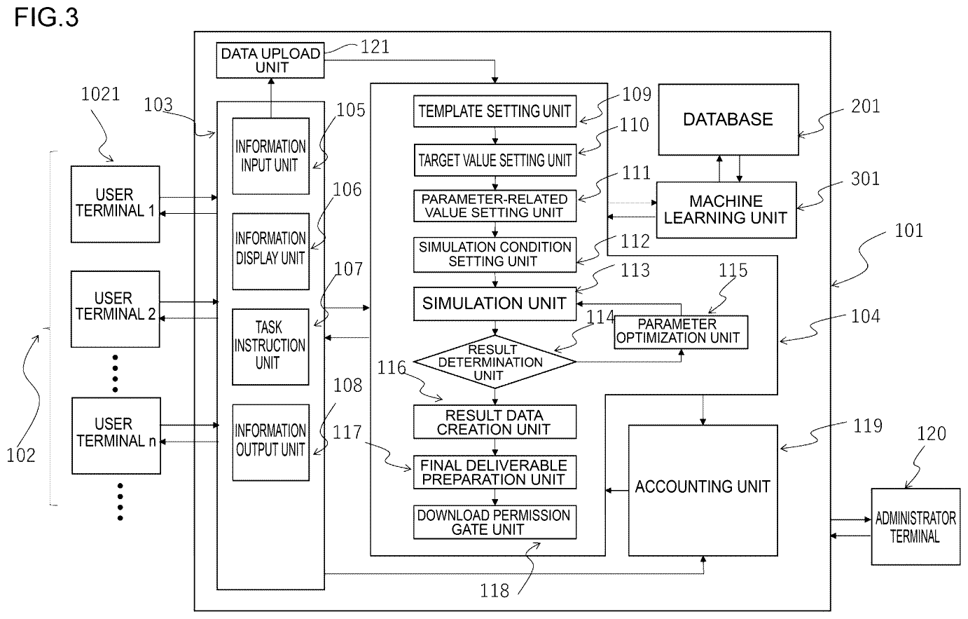

FIG. 3 is a block diagram of a system according to a third embodiment, in which the system of the second embodiment illustrated in FIG. 2 further includes a machine learning unit 301. The machine learning unit 301 automatically selects an optimal template, parameter-related values, and simulation conditions based on information such as a target value entered by the user terminal 1021 into the information input unit 105 of the user interface 103 using training data previously stored in the database 201. This can further improve the convenience of the user terminal 1021 and the processing efficiency of the simulation data generation system 101.

The machine learning unit 301 uses machine learning to identify training data to be used based on the training data stored in the database 201 with reference to at least one of the following: a target value entered by the user, a template selected by the user, a parameter-related value entered by the user, and simulation condition settings entered by the user. The machine learning unit 301 identifies at least one of the template selected by the user, the parameter-related value entered by the user, and the simulation condition settings entered by the user.

The database 201 may be supplemented as appropriate by the provider with additional and improved training data. Alternatively, the machine learning unit 301 may improve the database 201 while analyzing a history of simulation runs by the simulation data generation system 101.

That is, in the second embodiment, the processing unit 104 stores a history of simulation runs in the database 201. Additionally, in the third embodiment, the machine learning unit 301 analyzes the history of simulation runs stored in the database 201 and improves the database 201. This makes it possible to more appropriately select a template, a target value, parameters, and simulation conditions from the database 201, thereby further improving the convenience of the simulation data generation system 101.

Furthermore, a larger amount of data can be stored in the database 201 by storing a history of simulation runs that are of relatively low value to be stored, such as those in which the error is greater than the desired allowable error and those in which the final deliverable is not downloaded even though the error is equal to or less than the desired allowable error. As a result, the machine learning unit 301 can use a large amount of data as training data, which improves the accuracy of machine learning.

It is also possible to search the data stored in the database 201 for one that is close to the target characteristics. This makes it possible to find a compatible component.

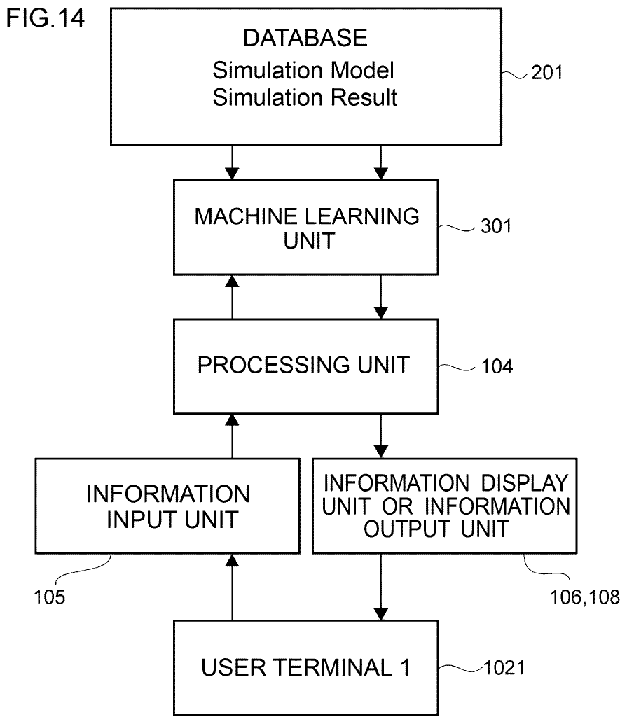

FIG. 14 illustrates an example of a procedure for searching for a compatible or alternative product. The user enters the characteristics of a component that they currently own from the user terminal 1021 through the information input unit 105. The processing unit 104 creates a simulation model and simultaneously obtains its simulation result. The machine learning unit 301 searches for a simulation model and its simulation result stored in the database 201 using the simulation model and the simulation result obtained by the simulation unit 113 as keys. The machine learning unit 301 extracts, from the database 201, a simulation model and its simulation result that are close to the simulation model and the simulation result obtained by the simulation unit 113. The machine learning unit 301 returns the simulation model and the simulation result extracted from the database 201 to the processing unit 104. The result determination unit 114 of the processing unit 104 calculates, if necessary, the error between the simulation result obtained by the simulation unit 113 and the simulation result extracted from the database 201. The result data creation unit 116 of the processing unit 104 returns the search results, such as the model number of an alternative product (the simulation model extracted from the database 201), a characteristic comparison result (the error between the simulation result obtained by the simulation unit 113 and the simulation result extracted from the database 201), and the simulation model (the simulation model extracted from the database 201), to the user terminal 1021 through the information display unit 106 or the information output unit 108. If the user already has a simulation model, it may be entered into the simulation data generation system 101 through the information input unit 105 to remove the process of creating a simulation model from a workflow.

### Fourth Embodiment

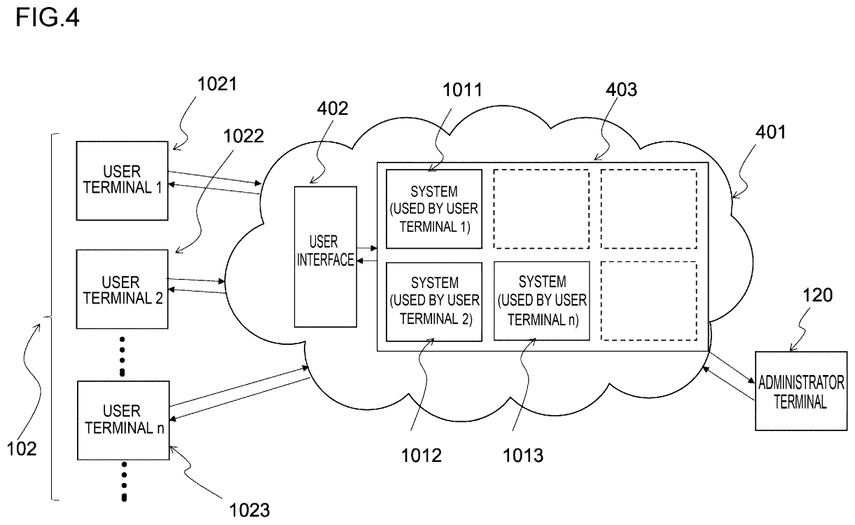

FIG. 4 is a conceptual diagram of a system according to a fourth embodiment, in which the entire system is implemented as a software as a service (Saas) system on a cloud 401.

In this case, when a plurality of user terminals 1021, 1022, and 1023 simultaneously access a processing unit 403, the cloud 401 automatically implements simulation data generation systems 1011, 1012, and 1013 on multiple hardware, thereby realizing an independent user interface 402, the processing unit 403, and the like. As a result, terminals in the user terminal group 102 can each perform processing using the simulation data generation system 1011, 1012, or 1013 without interfering with each other and without waiting for available hardware.

An independent provider, separate from the user terminal group 102, may use the administrator terminal 120 to build the simulation data generation system as a SaaS in a public cloud. In addition, the entity to which the user belongs may use the administrator terminal 120 to build a dedicated simulation data generation system in a public cloud or in an on-premises environment owned by the entity itself.

The mechanism by which the cloud 401 dynamically scales the CPU, memory, memory area, and the like according to the load is not the subject matter of this embodiment, and therefore a description thereof will not be provided.

While specific embodiments of the invention have been described and illustrated, it is to be understood that the invention is not limited to the embodiments disclosed herein. Various changes, modifications, and alterations may be made within the scope of the invention as defined in the appended claims.

According to some embodiments, a plurality of independent users with different purposes related to simulatable data may use a single common system, thereby realizing an efficient environment for generating simulation data for both the users and the provider that operates the system.

In the system of some embodiments, a database is implemented on a computer connected to a network, such as a cloud, to store software that performs two steps: selecting a template that can characterize a target object with parameters and automatically optimizing the parameters, and information required to execute the template and the software. The system is provided with a function that allows a user to directly access and operate the system to check the level of completion of a completed deliverable before paying a major portion of the compensation such as fees to a service provider. The system also has a means to determine whether or not to permit the provision of the deliverable after confirming the payment of the fee by the user, and it allows the provider to set determination criteria.

In some embodiments, a program based on a combination of template setting and parameter optimization using a simulator is implemented on a computer connected to a network such as a cloud to provide a means that allows a user to directly access the system and easily generate simulation data at any time, and at the same time, controls the download of the simulation data as a final deliverable by the user. This ensures that the system operator receives adequate compensation from the user. In addition, the system may be provided with a database that stores a plurality of templates and simulation conditions that the user can refer to and select to use, thereby increasing convenience. The system may also be provided with a machine learning tool so that it can automatically select and set a template and simulation data according to the user's intended use and target value.

In some embodiments, software that uses an algorithm is implemented in a cloud along with a user interface for the user to log in; the algorithm performs a simulation by combining a selected template and its parameters using a SPICE simulator, evaluates the difference between a target set by the user and the simulation result, and adjusts the parameters to reduce the difference. As a result, users who are not necessarily experts in generating simulation data can easily produce a deliverable with minimal initial investment; they can also check quantitative information about the quality of the deliverable, such as its accuracy, on a computer screen or the like before obtaining simulation data, i.e., the deliverable.

If the operator is a provider other than the user, a gate may be provided to stop the provision of a deliverable to the user unless the user pays the fee in accordance with an agreement between the service operator and the simulation data generation system of the embodiments, thereby providing the service operator with a reliable opportunity for billing to receive adequate compensation.

The embodiments as described above may simultaneously achieve the user's goal of efficiently obtaining a deliverable and the service operator's goal of securing stable profits by attracting a large number of users, while also solving a problem common to both parties: the shortage of expert engineers.

As described above, the simulation data generation system of the embodiments can be used for applications such as the development of a simulation model for semiconductor devices and stand-alone electronic devices, circuit design capable of simulating electronic circuits, and the like.

The simulation model need not necessarily be in the SPICE format and may be in the IBIS format or a format such as Verilog-A, Verilog-AMS, VHDL, VHDL-AMS, or Modelica. A simulator capable of simulating a simulation model in such a format may be used in the simulation unit 113 instead of the SPICE simulator.

The embodiments are applicable not only to the fields of electronic components and electronic equipment but also to objects related to machinery and natural phenomena, as long as the objects can be represented by a computer with a template and its parameters. For example, the embodiments may be applied to the development of a simulation model in a case where the system of an electrically controlled automobile that combines electrical and mechanical systems is modeled in VHDL-AMS to simulate the actual operation of the system in which the electrical and mechanical systems interact with each other. It is well known that a thermal simulation model can be represented by an electrical circuit, and the embodiments may also be applied to the development of a thermal conduction model represented by an equivalent circuit.

According to some embodiments, in the control circuit, the CPU loads a computer program from the ROM into the RAM and executes it, thereby realizing a server that operates as the processing unit. In addition, the program of the embodiments can be installed in a server (information processing apparatus) to be implemented as a program executed by the control circuit of the server. Furthermore, the program may be provided to end users as so-called packaged software. In this case, the program of the embodiments is executed by the control circuit in the personal computers (information processing apparatuses) of the end users.

### Additional Notes

According to an embodiment, an information processing apparatus comprises a processing unit including: a template setting unit that sets a template for a predetermined object according to settings on a user terminal to generate a simulation result in response to input of a parameter; a parameter-related value setting unit that sets a value related to the parameter according to the settings on the user terminal; a simulation unit that enters the parameter set by the parameter-related value setting unit into the template set by the template setting unit to run a simulation to generate a simulation result; and a result data creation unit that presents information based on the simulation result generated by the simulation unit to the user terminal.

In the embodiment, the simulation unit may generate a simulation result by entering the parameter into the template. In addition, the result data creation unit presents information based on the simulation result, allowing the user to check the information based on the simulation result before obtaining a deliverable.

The processing unit may further include: a target value setting unit that sets a target value for simulation data of the object; a result determination unit that compares the simulation result with the target value to determine an error; and a parameter optimization unit that optimizes the parameter with reference to the target value when the error is greater than a desired allowable error, and causes the simulation unit to rerun the simulation.

In the embodiment, the parameter may be automatically optimized.

The information processing apparatus may further comprise a database that stores a plurality of templates, wherein the template setting unit may select a predetermined template from the database in response to a selection on the user terminal.

The result data creation unit may create a processing result evaluation report that compares the simulation result to the target value when the error is equal to or less than the desired allowable error, and present it to the user as the information based on the simulation result.

In the embodiment, the user can check the processing result evaluation report before obtaining a deliverable.

The processing unit may further include: a final deliverable preparation unit that creates a final report that contains the simulation data as a deliverable including the template and the optimized parameter; and a download permission gate unit that controls whether or not the final report that contains the simulation data as a deliverable is to be provided to the user.

In the embodiment, after the user checks the processing result evaluation report based on the simulation result and is allowed to be provided with the final report that contains the simulation data as a deliverable, the user can download the simulation data as a final deliverable. In this manner, a function that controls the user's download of the simulation data as a final deliverable ensures that the system operator receives adequate compensation from the user.

The information processing apparatus may further comprise an accounting unit that calculates a usage fee required to generate the deliverable, wherein the download permission gate unit may control whether or not the final report that contains the deliverable is to be provided to the user based on the usage fee.

In the embodiment, it is possible to determine whether or not to permit the provision of the deliverable after confirmation of the payment of the usage fee from the user and allow the provider to set determination criteria.

The information processing apparatus may further comprise a user interface that is accessible by the user terminal via a network.

The user interface may be a web system.

In the embodiment, a plurality of independent users with different purposes use a single common WEB system, thereby realizing an efficient environment for generating simulation data for both the users and the provider that operates the system.

The user interface may include an information input unit, wherein the information input unit may include a preliminary simulation unit that simulates a simulation model to obtain a target value, and the information input unit may set the target value in the target value setting unit.

This allows the preliminary simulation unit to set an appropriate target value without requiring the user to set a target value manually.

The information input unit may further include a target value adjustment unit that adjusts the target value obtained by the preliminary simulation unit, wherein the information input unit may set the adjusted target value in the target value setting unit.

When the target value adjustment unit adjusts the target value, the target value to be set in the target value setting unit can be made more appropriate.

The simulation model used as the preliminary simulation unit may be the same as or different from the simulator used as the simulation unit.

This makes it possible to set a more appropriate target value.

The simulation unit, the result determination unit, and the parameter optimization unit may continue the loop process until the result determination unit determines that the error is equal to or less than the desired allowable error.

In the embodiment, the automatic optimization of the parameter can be achieved.

The simulation unit may utilize the same simulator as that used by the user.

For example, the constants of a circuit are typically optimized by simulating the operation of the circuit using a simulator; however, it is difficult and inefficient to optimize all the circuit constants in a circuit. The simulation unit enables efficient simulation.

The database may store a plurality of parameter-related values, and the parameter-related value setting unit may select the value related to the parameter from the database.

Part of the contents of the database may be specified in advance in a template. It is possible to search for a combination of parameters that satisfies all target values by setting, for example, a default parameter as the value related to the parameter in the parameter-related value setting unit.

The database may store a plurality of simulation conditions, and the processing unit may further include a simulation condition setting unit that sets the simulation conditions with reference to the database.

It is possible to search for a combination of parameters that satisfies all target values by setting, for example, the voltage, analysis mode, and the like in the simulation condition setting unit.

The processing unit may store a history of simulation runs in the database.

This allows the results of simulations performed by a group of user terminals to be stored in the database and shared among the user terminals in the future, thereby improving the simulation data generation system and making it more convenient.

The information processing apparatus may further comprise a machine learning unit that uses machine learning to identify training data to be used based on training data stored in the database with reference to at least one of the following: the target value entered by the user, the template selected by the user, the value related to the parameter entered by the user, and simulation condition settings entered by the user.

This can further improve the convenience of the user terminal and the processing efficiency of the simulation data generation system. In addition, the machine learning unit can improve the database while storing and analyzing a history of simulation runs by the simulation data generation system.

The machine learning unit may analyze the history of simulation runs stored in the database to improve the database.

This makes it possible to more appropriately select a template, a target value, parameters, and simulation conditions from the database, thereby further improving the convenience of the simulation data generation system.

The machine learning unit may identify at least one of the following: the template selected by the user, the value related to the parameter entered by the user, and the simulation condition settings entered by the user.

This allows the machine learning unit to identify, using machine learning, training data to be used based on training data stored in at least one of the following databases: a template database, a parameter-related value database, and a simulation condition database, with reference to at least one of the following: the target value entered by the user, the template selected by the user, the value related to the parameter entered by the user, and the simulation condition settings entered by the user.

The simulation data may be electronic data that can be simulated by a simulator and include SPICE parameters of a semiconductor integrated circuit, an equivalent circuit model, an IBIS model, schematic data representing a schematic of an electronic circuit, or a netlist.

This allows anyone to obtain the simulation result, even if, for example, they are not a specialized engineer well-versed in the operating principles of the device and SPICE.

According to an embodiment, a computer program causes the control circuit of an information processing apparatus to operate as a processing unit including: a template setting unit that sets a template for a predetermined object according to settings on a user terminal to generate a simulation result in response to input of a parameter; a parameter-related value setting unit that sets a value related to the parameter according to the settings on the user terminal; a simulation unit that enters the parameter set by the parameter-related value setting unit into the template set by the template setting unit to run a simulation to generate a simulation result; and a result data creation unit that presents information based on the simulation result generated by the simulation unit to the user terminal.

According to the embodiments, a user may obtain a target object easily and at a low cost.

1. An information processing apparatus, comprising processing circuitry configured to:
set a template for a predetermined object according to settings on a user terminal to generate a simulation result in response to input of a parameter;
set a value related to the parameter according to the settings on the user terminal;
enter the parameter into the template to run a simulation to generate a simulation result; and
present information based on the generated simulation result to the user terminal.

2. The information processing apparatus according to claim 1, wherein the processing circuitry is further configured to:
set a target value for simulation data of the object;
compare the simulation result with the target value to determine an error; and
optimize the parameter with reference to the target value when the error is greater than a desired allowable error to rerun the simulation.

3. The information processing apparatus according to claim 2,
further comprising a database that stores plurality of templates,
wherein the processing circuitry is further configured to select a predetermined template from the database in response to a selection on the user terminal.

4. The information processing apparatus according to claim 2, wherein the processing circuitry is further configured to:
create a processing result evaluation report that compares the simulation result to the target value when the error is equal to or less than the desired allowable error; and
present the processing result evaluation report to a user as the information based on the simulation result.

5. The information processing apparatus according to claim 2, wherein the processing circuitry is further configured to:
create a final report that contains the simulation data as a deliverable including the template and the optimized parameter; and
control whether or not the final report is to be provided to a user.

6. The information processing apparatus according to claim 5, wherein the processing circuitry is further configured to:
calculate a usage fee required to generate the deliverable; and
control whether or not the final report is to be provided to the user based on the usage fee.

7. The information processing apparatus according to claim 2, further comprising a user interface that is accessible by the user terminal via a network.

8. The information processing apparatus according to claim 7, wherein the user interface is a web system.

9. The information processing apparatus according to claim 7, wherein
the user interface includes an input unit, and
the processing circuitry is further configured to run a preliminary simulation of a simulation model entered through the input unit to obtain a target value; and
set the target value.

10. The information processing apparatus according to claim 9, wherein the processing circuitry is further configured to:
adjust the target value obtained by the preliminary simulation; and
set the adjusted target value.

11. The information processing apparatus according to claim 9, wherein the simulation model used for the preliminary simulation corresponds to or is different from a simulator used for the simulation.

12. The information processing apparatus according to claim 2, wherein the processing circuitry is further configured to continue a loop process until it is determined that the error is equal to or less than the desired allowable error.

13. The information processing apparatus according to claim 1, wherein the processing circuitry comprises a same simulator as that used by a user.

14. The information processing apparatus according to claim 3, wherein
the database stores a plurality of parameter-related values, and
the processing circuitry is further configured to select the value related to the parameter from the database.

15. The information processing apparatus according to claim 3, wherein
the database stores a plurality of simulation conditions, and
the processing circuitry is further configured to set the simulation conditions with reference to the database.

16. The information processing apparatus according to claim 3, wherein the processing circuitry is further configured to store a history of simulation runs in the database.

17. The information processing apparatus according to claim 16, wherein the processing circuitry is further configured to use machine learning to identify training data to be used based on training data stored in the database with reference to at least one of the following: the target value entered by a user, the template selected by the user, the value related to the parameter entered by the user, and simulation condition settings entered by the user.

18. The information processing apparatus according to claim 17, wherein the processing circuitry is further configured to analyze the history of simulation runs stored in the database to improve the database.

19. The information processing apparatus according to claim 17, wherein the processing circuitry is further configured to use machine learning to identify at least one of the following: the template selected by the user, the value related to the parameter entered by the user, and the simulation condition settings entered by the user.

20. The information processing apparatus according to claim 2, wherein the simulation data is electronic data that can be simulated by a simulator and includes: simulation program with integrated circuit emphasis (SPICE) parameters of a semiconductor integrated circuit, an equivalent circuit model, an input/output buffer information specification (IBIS) model, schematic data representing a schematic of an electronic circuit, or a netlist.

21. The information processing apparatus according to claim 2, wherein the processing circuitry is further configured to:
create a progress report that contains the simulation result when the error is greater than the desired allowable error; and
present the progress report to a user as the information based on the simulation result.

22. A computer program product comprising a non-transitory computer-usable medium having a computer-readable program code embodied therein, the computer-readable program code, when executed on a computer, causing the computer to:
set a template for a predetermined object according to settings on a user terminal to generate a simulation result in response to input of a parameter;
set a value related to the parameter according to the settings on the user terminal;
enter the parameter into the template to run a simulation to generate a simulation result; and
present information based on the generated simulation result to the user terminal.
